(19) United States
(12) Patent Application Publication
(10) Pub. No.: US 2017/0277107 A1
(43) Pub. Date: Sep. 28, 2017

(54) WIRING STRUCTURE AND IMAGE FORMING APPARATUS

(71) Applicant: FUJI XEROX CO., LTD., Tokyo (JP)

(72) Inventors: Makoto OKADO, Yokohama-shi (JP); Takahiro HORIGUCHI, Yokohama-shi (JP); Fumiya SHISEKI, Yokohama-shi (JP)

(73) Assignee: FUJI XEROX CO., LTD., Tokyo (JP)

(21) Appl. No.: 15/258,801

(22) Filed: Sep. 7, 2016

(30) Foreign Application Priority Data
Mar. 25, 2016 (JP) 2016-062379

(51) Int. Cl. B41J 2/385; H05K 1/14; H05K 1/02

(52) U.S. Cl. CPC G03G 15/80; H05K 1/14; H05K 1/0215

(57) ABSTRACT

According to an aspect of the invention, a wiring structure includes a pair of printed circuit boards, a cable that connects the pair of printed circuit boards, and a grounding member that causes grounding of the cable in a region including a position separated from a connection end between the printed circuit board and the cable by a distance obtained by dividing a radiation mode length of a system including the cable and the pair of printed circuit boards as antennas by 2.

### CROSS-REFERENCE TO RELATED APPLICATIONS

This application is based on and claims priority under 35 USC 119 from Japanese Patent Application No. 2016-062379 filed Mar. 25, 2016.

### BACKGROUND

Technical Field

The present invention relates to a wiring structure and an image forming apparatus.

### SUMMARY

According to an aspect of the invention, a wiring structure includes: a pair of printed circuit boards; a cable that connects the pair of printed circuit boards; and a grounding member that causes grounding of the cable in a region including a position separated from a connection end between the printed circuit board and the cable by a distance obtained by dividing a radiation mode length of a system including the cable and the pair of printed circuit boards as antennas by 2.

### BRIEF DESCRIPTION OF THE DRAWINGS

Exemplary embodiments of the present invention will be described in detail based on the following figures, wherein:

FIG. 1 is a schematic view showing a configuration of an image forming apparatus according to the exemplary embodiment;

FIG. 2 is a perspective view showing a configuration of a print head according to the exemplary embodiment;

FIG. 3 is a perspective view showing a configuration of a wiring structure according to the exemplary embodiment;

FIG. 4 is a plan view showing a configuration of the wiring structure according to the exemplary embodiment;

FIG. 5 is a graph showing frequency distribution of an oscillatory system of a cable and a printed wiring board according to a comparative example; and

FIG. 6 is a graph showing frequency distribution of an oscillatory system of a cable and a printed wiring board according to the exemplary embodiment.

### DETAILED DESCRIPTION

Hereinafter, an example of the exemplary embodiment according to the invention will be described with reference to the drawings.

### [Image Forming Apparatus 10]

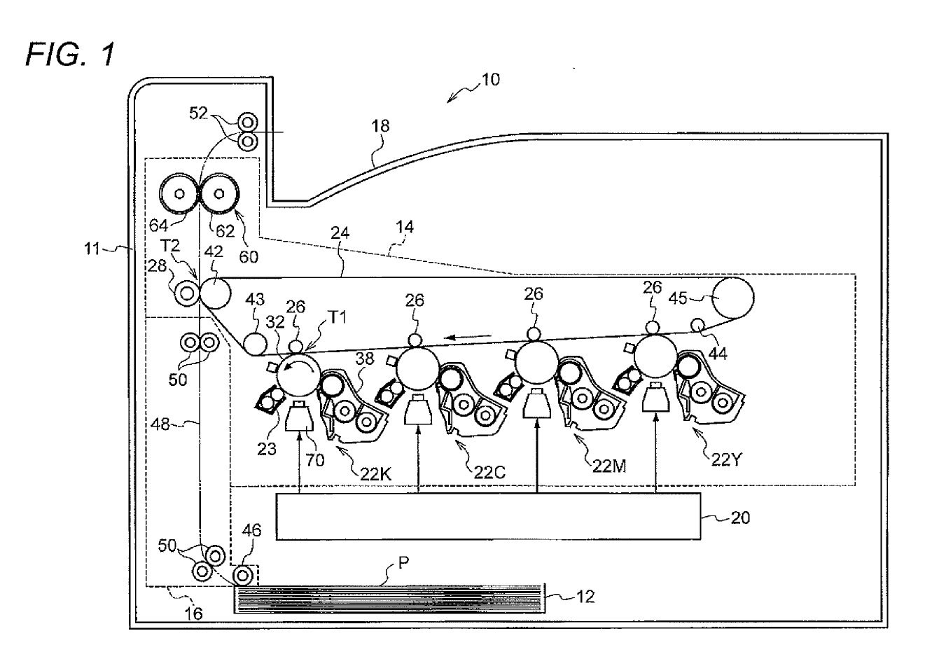

First, a configuration of an image forming apparatus 10 will be described. FIG. 1 is a schematic view showing the configuration of the image forming apparatus 10.

As shown in FIG. 1, the image forming apparatus 10 includes an image forming apparatus main body 11 in which each constituent element is provided. A containing unit 12 which contains a recording medium P such as paper and an image forming section 14 which forms an image on the recording medium P are provided in the image forming apparatus main body 11. A transport unit 16 which transports the recording medium P from the containing unit 12 to the image forming section 14 and a control board 20 (an example of a printed circuit board) as a control unit which controls operations of each unit of the image forming apparatus 10 are further provided in the image forming apparatus main body 11. An exit unit 18 to which the recording medium P where an image is formed by the image forming section 14 is discharged is provided on the upper portion of the image forming apparatus main body 11.

The image forming section 14 includes image forming units 22Y, 22M, 22C, and 22K (hereinafter, referred to as 22Y to 22K) as formation units which forms yellow (Y), magenta (M), cyan (C), and black (K) toner images, and an intermediate transfer belt 24 (transfer body) to which the toner images formed by the image forming units 22Y to 22K are transferred. The image forming section 14 includes a primary transfer roll 26 which transfers the toner images formed by the image forming units 22Y to 22K to the intermediate transfer belt 24, a secondary transfer roll 28 which transfers the toner image transferred to the intermediate transfer belt 24 from the intermediate transfer belt 24 to the recording medium P, and a fixing device 60 which fixes the images formed on the recording medium P to the recording medium P. The configuration of the image forming section 14 is not limited to the configuration described above, and may have other configurations, as long as images are formed on the recording medium P.

Each of the image forming units 22Y to 22K includes a photoreceptor 32 which rotates in one direction (for example, counterclockwise of FIG. 1). Since each of the image forming units 22Y to 22K has the same configuration, reference numerals of each unit of the image forming units 22Y, 22M, and 22C are omitted in FIG. 1.

Around each photoreceptor 32, a charging device 23 which charges the photoreceptor 32, a print head 70 (an example of an exposure device) which exposes the photoreceptor 32 charged by the charging device 23 to form an electrostatic latent image to the photoreceptor 32, and a developing device 38 which develops the electrostatic latent image formed by the print head 70 to form a toner image are sequentially provided from the upstream side of the photoreceptor 32 in a rotation direction.

The intermediate transfer belt 24 is formed in a ring shape and is disposed on the upper side of the image forming units 22Y to 22K. Winding rolls 42, 43, 44, and 45 on which the intermediate transfer belt 24 is wound are provided on an inner circumference of the intermediate transfer belt 24. The intermediate transfer belt 24 orbits (rotates) in one direction (for example, clockwise of FIG. 1) while contacting with each photoreceptor 32, due to the rotation of the winding roll 45, for example. The winding roll 42 is a facing roll which faces the secondary transfer roll 28.

The primary transfer roll 26 faces the photoreceptor 32 with the intermediate transfer belt 24 interposed therebetween. The position between the primary transfer roll 26 and the photoreceptor 32 is set as a primary transfer position T1 where a toner image formed on the photoreceptor 32 is transferred to the intermediate transfer belt 24.

A primary transfer voltage (primary transfer current) having a polarity opposite to a toner polarity is applied to the primary transfer roll 26. Accordingly, a primary transfer electric field is formed between the photoreceptor 32 and the primary transfer roll 26, an electrostatic force is operated to the toner image formed on the photoreceptor 32, and the toner image is transferred to the intermediate transfer belt 24 in the primary transfer position T1.

The secondary transfer roll 28 faces the winding roll 42 with the intermediate transfer belt 24 interposed therebetween. A position between the secondary transfer roll 28 and the winding roll 42 is set as a secondary transfer position T2 where the toner image transferred to the intermediate transfer belt 24 is transferred to the recording medium P.

A secondary transfer voltage (secondary transfer current) having a polarity opposite to a toner polarity is applied to the secondary transfer roll 28. Accordingly, a secondary transfer electric field is formed between the winding roll 42 and the secondary transfer roll 28, an electrostatic force acts to the toner image formed on the intermediate transfer belt 24, and the toner image is transferred to the recording medium P in the secondary transfer position T2.

As shown in FIG. 1, the transport unit 16 includes a delivery roll 46 which delivers the recording medium P contained in the containing unit 12, a transporting path 48 to which the recording medium P delivered to the delivery roll 46 is transported, and plural transporting rolls 50 which transport the recording medium P delivered by the delivery roll 46 to the downstream side.

The fixing device 60 is disposed on the downstream side of the secondary transfer position T2 in a transporting direction. The fixing device 60 includes a heating roll 62 and a pressure roll 64. In the fixing device 60, the toner image transferred from the intermediate transfer belt 24 to the recording medium P is fixed to the recording medium P by heating performed by the heating roll 62 and pressurizing performed by the pressure roll 64. A transporting roll 52 which discharges the recording medium P to which the toner image is fixed, to the exit unit 18 is provided on the downstream side of the fixing device 60 in the transporting direction.

Next, an image forming operation in the image forming apparatus 10 according to the exemplary embodiment of forming an image on a recording medium P will be described.

In the image forming apparatus 10 according to the exemplary embodiment, the recording medium P which is delivered by the delivery roll 46 from the containing unit 12 is transported to the secondary transfer position T by the transporting roll 50 (see FIG. 1).

Meanwhile, in each of the image forming units 22Y to 22K, the photoreceptor 32 charged by the charging device 23 is exposed by the print head 70 to form an electrostatic latent image on the photoreceptor 32. This electrostatic latent image is developed by the developing device 38 to form a toner image on the photoreceptor 32. The toner image having each color formed by the image forming units 22Y to 22K is superimposed on the intermediate transfer belt 24 in the primary transfer position T1 and transferred to form a color image. The color image formed by the intermediate transfer belt 24 is transferred to the recording medium P in the secondary transfer position T2.

The recording medium P to which the color image is transferred is transported to the fixing device 60 and the transferred color image is fixed by the fixing device 60. The recording medium P to which the color image is fixed is discharged to the exit unit 18 by the transporting roll 52. As described above, a series of the image forming operations are performed.

### [Print Head 70]

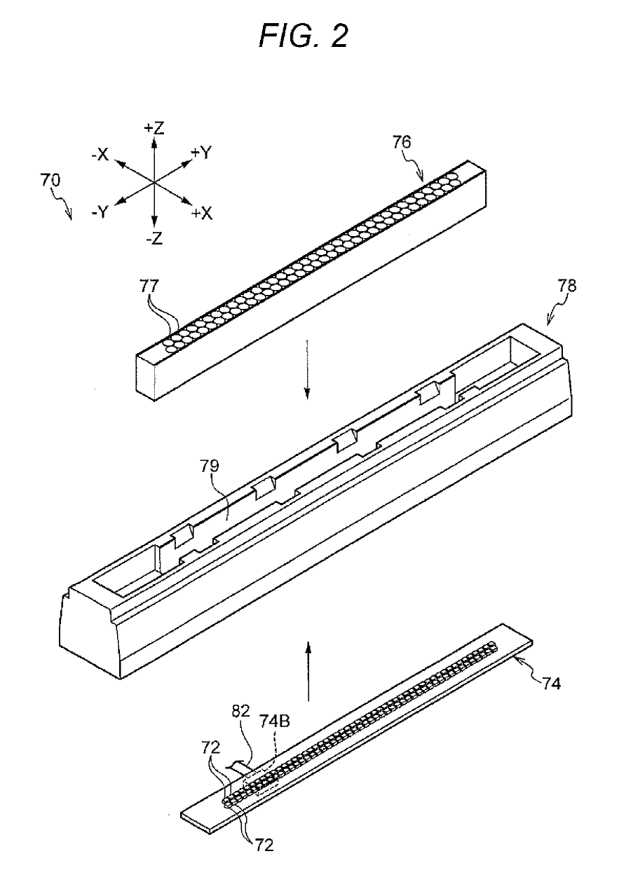

As shown in FIG. 2, the print head 70 includes a printed wiring board 74 (an example of an elongated board), a lens array 76 as an optical member, and a housing 78 to which the printed wiring board 74 and the lens array 76 are attached.

A direction along an axial direction of the photoreceptor 32 (see FIG. 1) is set as a Y direction, a direction which is orthogonal to the Y direction and in which the printed wiring board 74 and the lens array 76 are attached to the housing 78 is set as a Z direction, and a direction orthogonal to the Y direction and the Z direction is set as an X direction. In a case where it is necessary to distinguish one side and the other side in the X, Y, and Z directions, the one side is positive (+) and the other side is negative (−).

The printed wiring board 74 is formed in an elongated and plate-like shape in which the X direction is a short direction, the Y direction is a longitudinal direction, and the Z direction is a thickness direction. Light emitting elements 72 are mounted on a surface of the printed wiring board 74 on the positive Z direction side in a zigzag pattern. The light emitting elements 72 are, for example, configured with plural light emitting diodes (LED), that is, LED chips including plural light emitting diodes.

A circuit (not shown) containing a driving circuit which drives the light emitting elements 72 to cause light emission of the light emitting elements 72 and a terminal 74B electrically connected to the circuit are disposed on a surface of the printed wiring board 74 on the negative Z direction side. The terminal 74B is disposed in a position shifted to one end side (negative Y direction end side) from the center of the printed wiring board 74 in the longitudinal direction (Y direction).

The lens array 76 is formed in a rectangular parallelepiped shape by setting the X direction as a short direction, the Y direction as a longitudinal direction, and the Z direction as a height direction. In the lens array 76, plural rod lenses 77 through which light emitted from each LED of each light emitting element 72 transmits are disposed in a zigzag pattern. Accordingly, an image is formed on the photoreceptor 32 with the light emitted from each LED of the light emitting element 72 and transmitting the rod lens 77 (see FIG. 1).

The housing 78 is formed of a resin formed with a resin material (liquid crystal polymer as an example), and as shown in FIG. 2, the housing has a substantially rectangular parallelepiped shape, the outer shape of which extends in the Y direction. A penetration hole 79 which extends in the Y direction and is penetrated in the Z direction is formed on the housing 78.

The lens array 76 is inserted to the penetration hole 79 in the negative Z direction to be attached to the housing 78. The printed wiring board 74 is attached to the end portion around the penetration hole 79 in the positive Z direction.

The lens array 76 and the light emitting elements 72 of the printed wiring board 74 face each other at an interval in a state where the lens array 76 and the printed wiring board 74 are attached to the housing 78.

### [Wiring Structure 80]

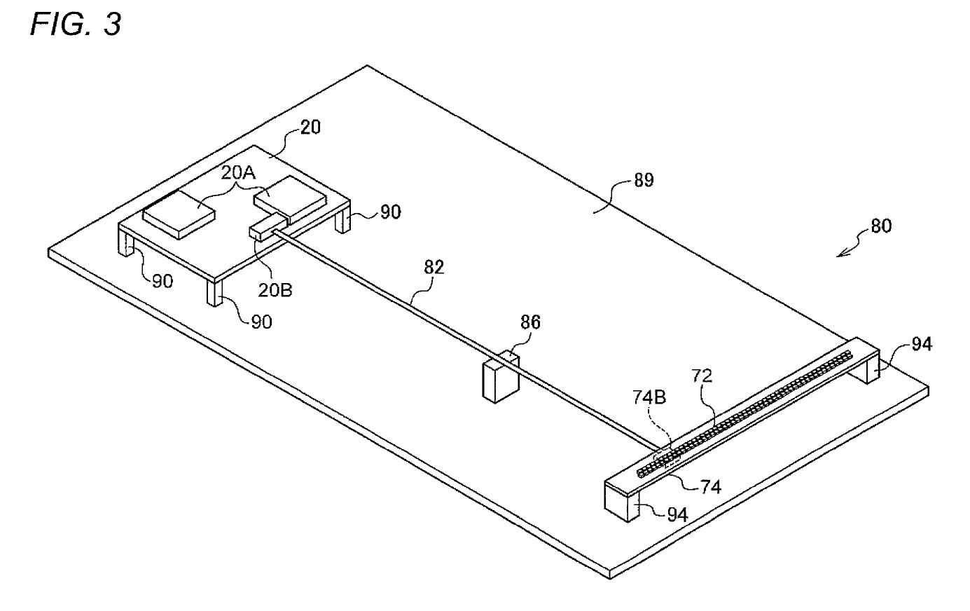

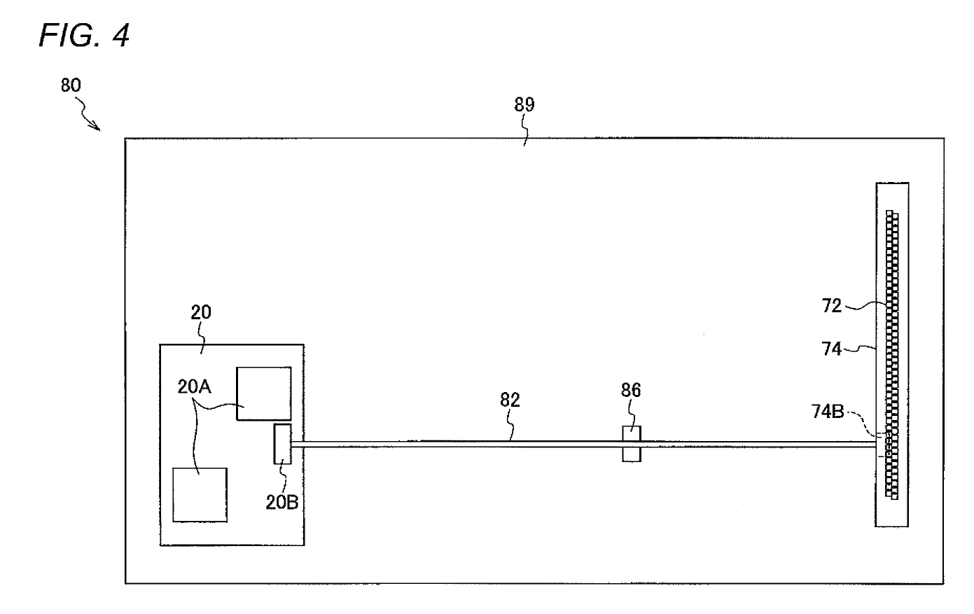

The image forming apparatus 10 includes a wiring structure 80 which will be described later. As shown in FIG. 3 and FIG. 4, the wiring structure 80 includes the printed wiring board 74 described above, the control board 20 described above, a cable 82, a grounding member 86, and a metal frame 89. FIG. 3 and FIG. 4 schematically show the wiring structure 80.

The metal frame 89 is a part of a frame configuring the image forming apparatus main body 11. That is, in FIG. 3 and FIG. 4, a part of the frame configuring the image forming apparatus main body 11 is cut and shown as the metal frame 89. In FIG. 3 and FIG. 4, the metal frame 89 is shown in a flat plate shape, but the metal frame 89 may be formed in a shape which is formed with convex concave portions, cut-out portions, or holes, or is bent or curved.

The printed wiring board 74 is disposed in an elongated shape in a direction having an angle (specifically, right angle) with respect to the longitudinal direction of a cable 82, in a plan view. That is, the printed wiring board 74 is set as an elongated board formed in an elongated shape in a direction different from the longitudinal direction of the cable 82.

As described above, in the printed wiring board 74, the light emitting elements 72 are disposed on one surface (surface on the positive Z direction side of FIG. 2), and the terminal 74B is disposed on the other surface (surface on the negative Z direction side of FIG. 2).

The terminal 74B is disposed in a position shifted to one end side from the center of the printed wiring board 74 in the longitudinal direction. A length (dimension) of the printed wiring board 74 in the longitudinal direction (Y direction of FIG. 2) is, for example, set as 230 mm.

The control board 20 includes a circuit 20A containing a control circuit which controls the operation of the light emitting elements 72 and a connector 20B as a terminal electrically connected to the circuit 20A.

The cable 82 is disposed to extend from the control board 20 to the printed wiring board 74. In FIG. 3 and FIG. 4, the cable 82 is shown to have a linear shape but may be disposed in a bent and curved state.

Specifically, the cable 82 is configured with a flexible flat cable (FFC). This cable 82 includes a signal line which transports a signal such as an image signal or a control signal, and a power line which supplies power.

As the cable 82, a coaxial cable, a twisted pair cable, or a flexible printed board (flexible printed circuit (FCP)) may be used.

One end portion of the cable 82 in the longitudinal direction is connected through the terminal 74B of the printed wiring board 74 and the other end portion of the cable 82 in the longitudinal direction is connected through a connector 20B of the control board 20. A length (dimension) of the cable 82 is, for example, set as 600 mm.

Power and a signal are transported from the control board 20 to the printed wiring board 74 via the cable 82 and the light emitting elements 72 emit light. Accordingly, an electrostatic latent image corresponding to an image signal is formed on the photoreceptor 32. As an image signal transported from the control board 20 to the printed wiring board 74, an image signal obtained by the control board 20 from an external device, is used, for example.

Each of the control board 20 and the printed wiring board 74 is grounded to the metal frame 98 (reference potential) by plural metal spacers 90 and 94.

In the exemplary embodiment, the grounding member 86 causes the cable 82 to ground to the metal frame 98 in an area including a position separated from the connection end (connector 20B) between the control board 20 and the cable 82 by a distance obtained by dividing a radiation mode length of a system including the cable 82, the control board 20, and the printed wiring board 74 as antennas by 2.

The grounding member 86 is configured with a conductive member (for example, metal member) formed in a block shape. As the grounding member 86, a tape, a clamp, a screw, a flat spring, a gasket, or a conductive sponge which bonds the cable 82 to the metal frame 98 may be used.

A length (length of the cable 82 along the length direction) of the grounding of the grounding member 86 is, for example, set as 10 mm to 50 mm.

Here, the radiation mode length is acquired as follows. In a system including the cable 82, the control board 20, and the printed wiring board 74 as antennas, when the connection end (connector 20B) between the control board 20 and the cable 82 is set as a starting point, an oscillatory system is formed with the cable 82 and the printed wiring board 74.

Each radiation mode length (electrical length) of the cable 82 and the printed wiring board 74 is acquired, and the radiation mode length when adding these lengths is 0-order radiation mode length (radiation mode length of a fundamental wave).

The radiation mode length of the cable 82 is acquired in terms of “k·c/f”. “k” is a wavelength shortening rate. “c” is a velocity of light. “f” is a resonance frequency (fundamental wave) of the cable 82. The wavelength shortening rate is acquired by using “1/√(εr×μr)”. “εr” is relative permittivity of the cable 82. “μr” is relative permeability of the cable 82.

The radiation mode length of the printed wiring board 74 is acquired in terms of “k·c/f”. “k” is a wavelength shortening rate. “c” is a velocity of light. “f” is a resonance frequency (fundamental wave) of the printed wiring board 74. The wavelength shortening rate is acquired by using “1/√(εr×μr)”. “εr” is relative permittivity of the printed wiring board 74. “μr” is relative permeability of the printed wiring board 74.

The grounding member 86 causes the cable 82 to ground in an area including a position separated from the connection end (connector 20B) between the control board 20 and the cable 82 by a distance obtained by dividing the 0-order radiation mode length by 2.

A resonance frequency of the cable 82 and a resonance frequency of the printed wiring board 74 are, for example, acquired by an electromagnetic field simulator. As the electromagnetic field simulator, MicroWaveStudio (manufactured by CST) is used, for example. A resonance frequency of the cable 82 and a resonance frequency of the printed wiring board 74 may be acquired by actual measurement.

In the exemplary embodiment, the position separated from connection end (connector 20B) between the control board 20 and the cable 82 by a distance obtained by dividing the 0-order radiation mode length by 2 is, for example, set as a position of 400 mm from the connection end between the control board 20 and the cable 82.

### [Operation According to Exemplary Embodiment]

In the exemplary embodiment, as described above, the grounding member 86 causes the cable 82 to ground to the metal frame 98 in an area including a position separated from the connection end (connector 20B) between the control board 20 and the cable 82 by a distance obtained by dividing a radiation mode length of a system including the cable 82, the control board 20, and the printed wiring board 74 as antennas by 2.

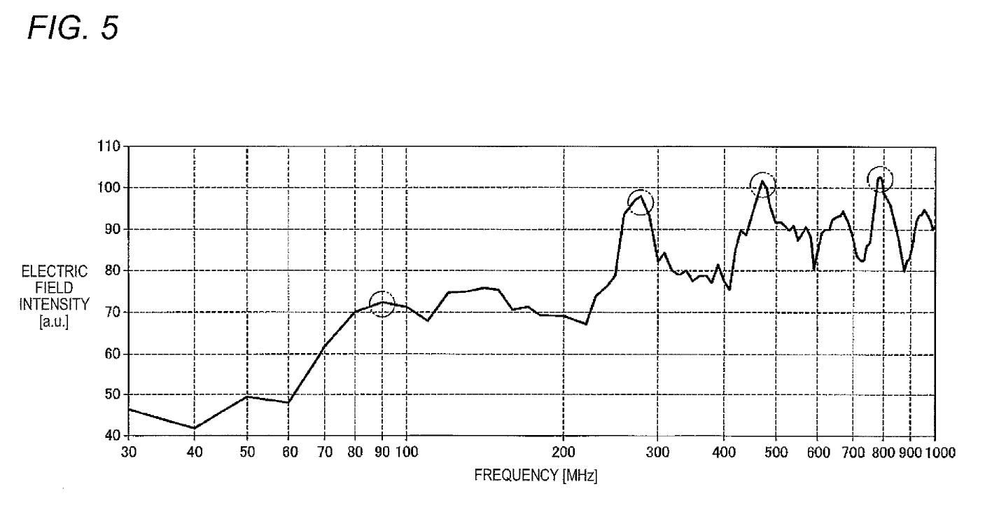

Here, in a configuration (comparative example) in which the cable 82 is not grounded between the control board 20 and the printed wiring board 74, the oscillatory system of the control board 20 and the printed wiring board 74 has the frequency distribution shown in FIG. 5.

In the comparative example, as shown in FIG. 5, the resonance frequency (fundamental wave) is shown as 90 MHz, a frequency of a primary harmonic wave is shown as 280 MHz, a frequency of a secondary harmonic wave is shown as 480 MHz, and a frequency of a tertiary harmonic wave is shown as 790 MHz. In the same manner as described above, the frequency distribution shown in FIG. 5 is acquired by an electromagnetic field simulator.

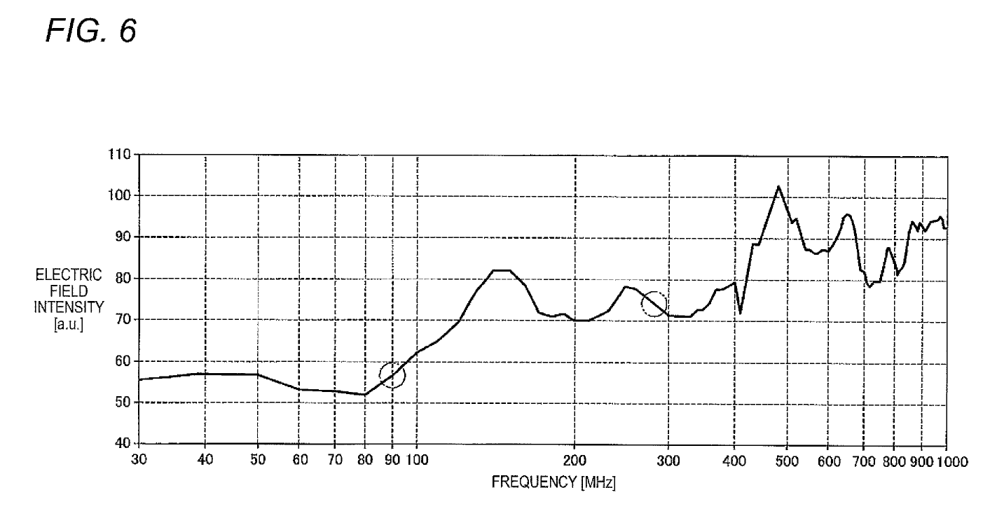

Meanwhile, in the configuration according to the exemplary embodiment, the oscillatory system of the cable 82 and the printed wiring board 74 has the frequency distribution shown in FIG. 6. In the exemplary embodiment, as shown in FIG. 6, the resonance frequency (fundamental wave) of 90 MHz of the control board 20 and the printed wiring board 74 is kept low, compared to the comparative example shown in FIG. 5. That is, according to the configuration of the exemplary embodiment, a radiation electromagnetic wave (electromagnetic noise) radiated from the control board 20 and the printed wiring board 74 is prevented, compared to the comparative example described above. As shown in FIG. 6, the frequency of the primary harmonic wave (280 MHz) is also kept low, compared to the comparative example shown in FIG. 5.

Since the grounding member 86 causes the grounding of the cable 82 in an area including the separated position by a distance obtained by dividing a radiation mode length by 2, the following mechanism is considered for the prevention of the radiation electromagnetic wave. That is, the maximum amplitude of the electromagnetic wave is obtained in the position separated by a distance obtained by dividing the radiation mode length by 2, and the grounding member 86 causes the grounding of the cable 82 in the region containing this position, and accordingly, the strength of the electromagnetic wave may be decreased. Therefore, the radiation electromagnetic wave (electromagnetic noise) is prevented, compared to a case where a cable is grounded in a region not including a position separated by a distance obtained by dividing a radiation mode length by 2.

### MODIFICATION EXAMPLE

In the exemplary embodiment, the grounding member 86 causes the grounding of the cable 82 in an area including a position separated from the connection end (connector 20B) between the control board 20 and the cable 82 by a distance obtained by dividing a 0-order radiation mode length by 2. In addition, the cable 82 may be grounded in a region including a position separated from the connection end (connector 20B) between the control board 20 and the cable 82 by a distance obtained by dividing a radiation mode length of a higher mode (harmonic wave) of a system including the cable 82, the control board 20, and the printed wiring board 74 as antennas by 2. That is, the cable 82 may be grounded at plural portions.

The radiation mode length of the higher mode (harmonic wave) is also acquired in the same manner as described above. That is, the wavelengths of the higher harmonic wave (primary or higher harmonic wave) of the cable 82 and the printed wiring board 74 are obtained, and the wavelength when adding these lengths is a radiation mode length (radiation mode length of the fundamental wave) of the higher mode.

The wavelength of the cable 82 is acquired in terms of “k·c/f”. “k” is a wavelength shortening rate. “c” is a velocity of light. “f” is a higher harmonic wave of the cable 82. The wavelength shortening rate is acquired by using “1/√(εr×μr)”. “εr” is relative permittivity of the cable 82. “μr” is relative permeability of the cable 82.

The wavelength of the printed wiring board 74 is acquired in terms of “k·c/f”. “k” is a wavelength shortening rate. “c” is a velocity of light. “f” is a higher harmonic wave of the printed wiring board 74. The wavelength shortening rate is acquired by using “1/√(εr×μr)”. “εr” is relative permittivity of the printed wiring board 74. “μr” is relative permeability of the printed wiring board 74.

In this configuration, the higher harmonic wave of the control board 20 and the printed wiring board 74 is prevented, compared to the comparative example shown in FIG. 5. Specifically, the radiation electromagnetic wave (electromagnetic noise) equal to or lower than 500 MHz is, for example, prevented.

The invention is not limited to the exemplary embodiment, and various modifications, changes, and improvements may be performed within a range not departing from the gist thereof. The modification example described above, for example, may be suitably configured with plural combinations.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A wiring structure comprising:
a pair of printed circuit boards;
a cable that connects the pair of printed circuit boards; and
a grounding member that causes grounding of the cable in a region including a position separated from a connection end between the printed circuit board and the cable by a distance obtained by dividing a radiation mode length of a system including the cable and the pair of printed circuit boards as antennas by 2.

2. The wiring structure according to claim 1,
wherein one of the pair of printed circuit boards is an elongated board formed in an elongated shape in a direction different from a longitudinal direction of the cable, and
the grounding member causes grounding of the cable in a region including a position separated from a connection end between other of the pair of printed circuit boards and the cable by a distance obtained by dividing a radiation mode length obtained by adding a radiation mode length of the elongated board and a radiation mode length of the cable by 2.

3. An image forming apparatus comprising:
the wiring structure according to claim 2;
a photoreceptor;
a charging device that electrically charges the photoreceptor;
an exposure device that exposes the photoreceptor charged by the charging device by a plurality of light emitting elements disposed along a longitudinal direction of the elongated board to form an electrostatic latent image; and
a developing device that develops the electrostatic latent image formed by the exposure device.
